(19) United States
(12) Patent Application Publication
(10) Pub. No.: US 2020/0348342 A1
(43) Pub. Date: Nov. 5, 2020

(54) METHOD AND APPARATUS FOR PROCESSING OSCILLOSCOPE DATA AND OSCILLOSCOPE

(71) Applicant: AUTEL INTELLIGENT TECHNOLOGY CORP., LTD., Shenzhen (CN)

(72) Inventors: Liangliang YANG, Shenzhen (CN); Xianchong Zhou, Shenzhen (CN)

(21) Appl. No.: 16/920,824

(22) Filed: Jul. 6, 2020

Related U.S. Application Data
(63) Continuation of application No. PCT/CN2019/070478, filed on Jan. 4, 2019.

(30) Foreign Application Priority Data
Jan. 5, 2018 (CN) 201810010432.9

(51) Int. Cl. G01R 13/02

(52) U.S. Cl. CPC G01R 13/029

(57) ABSTRACT

Embodiments of the present invention relate to the technical field of oscilloscopes and disclose a method and an apparatus for processing oscilloscope data and an oscilloscope. The method for processing the oscilloscope data includes: collecting measured data; storing the measured data in a storage space; sending a measured data read request to at least one function module, to cause the at least one function module to read the measured data from the storage space according to the measured data read request, respectively, and process the measured data; respectively receiving processing result information returned after the at least one function module processes the measured data; and outputting the processing result information. The measured data is stored in the storage space to call relevant data from the storage space as needed for observation, analysis, comparison or playback. In addition, the at least one function module reads and processes data from the storage space, respectively, to perform module-by-module processing on the measured data, thereby achieving the effect of outputting in a plurality of modes.

This application is a continuation application of International Application No. PCT/CN2019/070478, filed on Jan. 4, 2019, which claims priority of Chinese Patent Application No. 201810010432.9, filed on Jan. 5, 2018, which is incorporated herein by reference in its entirety.

### BACKGROUND

### Technical Field

The present application relates to the technical field of oscilloscopes, and in particular, to a method and an apparatus for processing oscilloscope data and an oscilloscope.

### Related Art

An oscilloscope is a basic test and measurement device in the electronics industry, and may convert an electrical signal that is invisible to the naked eye into a visible image, which is convenient for people to study the changes in various electrical phenomena. An oscilloscope can be used to observe waveform curves of various signal amplitudes over time, and may further be used to measure different parameters such as a voltage, a current, a frequency, a phase and an amplitude of the electrical signal.

A traditional oscilloscope directly displays the collected data or displays processed data, and does not store the collected data. Because the collected data is not stored, waveform data cannot be played back. In addition, module-by-module processing is not performed on the data, and a plurality of modes of output cannot be achieved, making it impossible for users to observe waveforms in a plurality of modes simultaneously.

### SUMMARY

The present invention is mainly intended to provide a method and an apparatus for processing oscilloscope data and an oscilloscope, so that the collected data can be stored, and a user can call relevant data as required for observation, analysis and comparison and can achieve the effect of outputting in a plurality of modes.

Embodiments of the present invention disclose the following technical solutions.

According to a first aspect, an embodiment of the present invention provides a method for processing oscilloscope data, the method including:

collecting measured data;

storing the measured data in a storage space;

sending a measured data read request to at least one function module, to cause the at least one function module to read the measured data from the storage space according to the measured data read request, respectively, and process the measured data;

respectively receiving processing result information that is returned after the at least one function module processes the measured data; and

outputting the processing result information.

In some embodiments, the storing the measured data in a storage space includes:

storing the measured data in pages on a screen-by-screen basis.

In some embodiments, the measured data read request is generated based on a current data read instruction or based on a playback instruction.

In some embodiments, the sending a measured data read request to at least one function module, to cause the at least one function module to read the measured data from the storage space according to the measured data read request, respectively, and process the measured data includes:

when the measured data read request is generated based on the current data read instruction, sending a measured data read request to at least one function module, to cause the at least one function module to read the measured data from the storage space in real time according to the measured data read request, respectively, and process the measured data; and

when the measured data read request is generated based on the playback instruction, sending a measured data read request to at least one function module, to cause the at least one function module to read, from the storage space according to the measured data read request, the measured data in a page indicated by the playback instruction, respectively, and process the measured data in the page indicated by the playback instruction.

In some embodiments, the outputting the processing result information includes:

converting the processing result information into an image, and displaying the image on an interface.

In some embodiments, the displaying the image on an interface includes:

displaying the image in a plurality of windows on the interface, an image displayed in one of the plurality of windows being an image obtained through conversion according to processing result information returned by one of the at least one function module; and/or

displaying the image in a single window on the interface, an image displayed in the single window being an image obtained through conversion according to processing result information returned by all function modules of the at least one function module.

In some embodiments, the method further includes:

receiving an operation of setting a baud rate of a measured device, and obtaining the baud rate of the measured device according to the operation of setting the baud rate of the measured device; and

determining, according to the baud rate of the measured device, a sampling frequency at which the measured data is collected.

In some embodiments, the measured device is an electronic component of an automobile.

In some embodiments, the storage space is a storage space of an oscilloscope.

In some embodiments, the storage space includes a storage space of an oscilloscope and a storage space that is of a terminal device and that is connected to an output end of the oscilloscope; and

the storing the measured data in a storage space includes:

when a data amount of the measured data is greater than a preset data amount threshold of the storage space of the oscilloscope, storing the measured data in the storage space of the terminal device.

In some embodiments, the terminal device is any of the following: a personal computer, a tablet and a smart phone.

According to a second aspect, an embodiment of the present invention provides an apparatus for processing oscilloscope data, the apparatus including:

a data collection module configured to collect measured data;

a data storage module configured to store the measured data in a storage space;

a request sending module configured to send a measured data read request;

at least one function module configured to receive the measured data read request, read the measured data from the storage space according to the measured data read request, respectively, and process the measured data;

a processing result information receiving module configured to respectively receive processing result information that is returned after the at least one function module processes the measured data; and

a processing result information output module configured to output the processing result information.

In some embodiments, the data storage module is specifically configured to:

store the measured data in pages on a screen-by-screen basis.

In some embodiments, the measured data read request is generated based on a current data read instruction or based on a playback instruction.

In some embodiments, the at least one function module is specifically configured to:

when the measured data read request is generated based on the current data read instruction, receive the measured data read request, read the measured data from the storage space in real time according to the measured data read request, and process the measured data; and

when the measured data read request is generated based on the playback instruction, receive the measured data read request, read, from the storage space according to the measured data read request, the measured data in a page indicated by the playback instruction, and process the measured data in the page indicated by the playback instruction.

In some embodiments, the processing result information output module includes:

an image display module configured to convert the processing result information into an image, and display the image on an interface.

In some embodiments, the image display module includes:

a multi-window display module configured to convert the processing result information into an image, and display the image in a plurality of windows on the interface, an image displayed in one of the plurality of windows being an image obtained through conversion according to processing result information returned by one of the at least one function module; and/or

a single-window display module configured to convert the processing result information into an image, and display the image in a single window on the interface, an image displayed in the single window being an image obtained through conversion according to processing result information returned by all function modules of the at least one function module.

In some embodiments, the apparatus further includes:

a baud rate obtaining module configured to receive an operation of setting a baud rate of a measured device, and obtain the baud rate of the measured device according to the operation of setting the baud rate of the measured device; and

a sampling frequency determining module configured to determine, according to the baud rate of the measured device, a sampling frequency at which the measured data is collected.

In some embodiments, the measured device is an electronic component of an automobile.

In some embodiments, the storage space is a storage space of an oscilloscope.

In some embodiments, the storage space includes a storage space of an oscilloscope and a storage space that is of a terminal device and that is connected to an output end of the oscilloscope; and

the data storage module is specifically configured to:

when a data amount of the measured data is greater than a preset data amount threshold of the storage space of the oscilloscope, store the measured data in the storage space of the terminal device.

In some embodiments, the terminal device is any of the following: a personal computer, a tablet and a smart phone.

According to a third aspect, an embodiment of the present invention provides an oscilloscope, including:

at least one processor; and

a memory communicably connected to the at least one processor, where

the memory stores instructions that may be executed by the at least one processor and that is executed by the at least one processor, so that the at least one processor can perform the foregoing method for processing the oscilloscope data.

According to a fourth aspect, an embodiment of the present invention provides a computer program product that includes a computer program stored in a non-volatile computer readable storage medium, the computer program including a program instruction that, when executed by an oscilloscope, causes the oscilloscope to perform the foregoing method for processing the oscilloscope data.

According to a fifth aspect, an embodiment of the present invention provides a non-volatile computer readable storage medium that stores a computer executable instruction that is used to cause an oscilloscope to perform the foregoing method for processing the oscilloscope data.

The beneficial effect of the embodiments of the present invention is that, in comparison to the prior art, in the embodiments of the present invention, the measured data is stored in the storage space, so as to call relevant data from the storage space as needed for observation, analysis, comparison or playback. In addition, the at least one function module reads and processes data from the storage space, respectively, to perform module-by-module processing on the measured data, thereby achieving the effect of outputting in a plurality of modes.

### BRIEF DESCRIPTION OF THE DRAWINGS

FIG. 1 is a schematic diagram of an application environment of a method for processing oscilloscope data according to an embodiment of the present invention;

FIG. 2 is a schematic diagram of a specific implementation principle for processing oscilloscope data according to an embodiment of the present invention;

FIG. 3 is a schematic flowchart of a method for processing oscilloscope data according to an embodiment of the present invention;

FIG. 4 is a schematic flowchart of a method for processing oscilloscope data according to another embodiment of the present invention;

FIG. 5 is a schematic diagram of a correspondence between each of at least one function module and a window during multi-window display according to an embodiment of the present invention;

FIG. 6 is a schematic diagram of an apparatus for processing oscilloscope data according to another embodiment of the present invention; and

FIG. 7 is a schematic diagram of an apparatus for processing oscilloscope data according to another embodiment of the present invention; and

FIG. 8 is a schematic structural diagram of hardware of an oscilloscope according to an embodiment of the present invention.

### DETAILED DESCRIPTION

In order to make the objectives, technical solutions, and advantages of the embodiments of the present invention clearer, the technical solutions in the embodiments of the present application will be described clearly and completely below with reference to the drawings in the embodiments of the present application. Obviously, the described embodiments are part of the embodiments of the present application, but not all of the embodiments. Based on the embodiments in the present application, all other embodiments obtained by a person of ordinary skill in the art without creative efforts shall fall within the protection scope of the present application.

In addition, the technical features involved in the various embodiments of the present invention described below can be combined with each other as long as they do not conflict with each other.

### Embodiment 1

Embodiments of the present invention provide a method and an apparatus for processing oscilloscope data and an oscilloscope. According to the method and apparatus for processing the oscilloscope data and the oscilloscope, collected data is stored, so that a user can call relevant data as required for observation, analysis and comparison and can achieve outputting in a plurality of modes. The following illustrates an application environment of the foregoing method.

Referring to FIG. 1, FIG. 1 is a schematic diagram of an application environment of a method for processing oscilloscope data according to an embodiment of the present invention. The application scenario includes: a measured device 10, an oscilloscope 20 and a terminal device 30. During use, the oscilloscope 20 is connected to the measured device 10 and the terminal device 30, respectively. First, the oscilloscope 20 collects the measured data generated by the measured device 10, stores and processes the measured data (stores the measured data in a storage space, and performs module-by-module processing on the measured data), and sends the processed data to the terminal device 30.

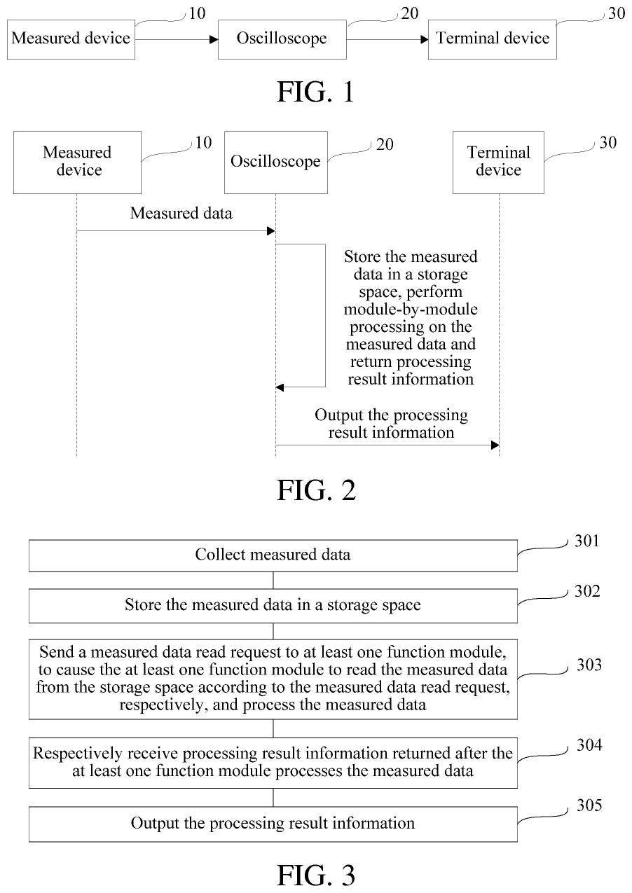

Referring to FIG. 2, FIG. 2 is a schematic diagram of a specific implementation principle for processing oscilloscope data according to an embodiment of the present invention. The specific implementation principle includes the following.

1. A measured device 10 generates measured data.

2. An oscilloscope 20 interacts with the measured device 10 to obtain, through collection, the measured data generated by the measured device 10.

3. After the measured data is obtained, the oscilloscope 20 stores the measured data in a storage space. The storage space may be a storage space of the oscilloscope 20 and may be a storage space of the terminal device 30. Because a size of the storage space of the oscilloscope 20 is generally limited, the data that may be stored is limited, and the amount of data that the terminal device 30 can store relative to the oscilloscope 20 is larger, when the data amount of the measured data is greater than a preset data amount threshold, the measured data may be stored in the storage space of the terminal device 30. The measured data is stored in the storage space of the terminal device 30, so that the size of the stored data is only limited by memory of the terminal device 30, but not affected by memory of the oscilloscope 20, thereby effectively resolving a problem of storing a large amount of data.

4. The oscilloscope 20 sends a measured data read request to at least one function module, to cause the at least one function module to read the measured data from the storage space according to the measured data read request, respectively, and process the measured data.

Each of the at least one function module may read the measured data from the storage space according to the measured data read request, and process the measured data respectively. For example, the at least one function module may include, but is not limited to, a spectrum module, a mathematical operation module, a decoding module, and the like. The spectrum module, the mathematical operation module and the decoding module may respectively read the measured data from the storage space and process the measured data respectively. The spectrum module processes the measured data to display a frequency domain image, that is, a spectrum graph, on an interface. The mathematical operation module may perform a mathematical operation (such as addition, subtraction, multiplication and division) on the measured data to display, on the interface, an image obtained after addition, subtraction, multiplication and division processing is performed on the measured data. The decoding module may decode the measured data to display, on the interface, a decoding result obtained after the measured data is decoded.

The measured data read request is generated based on a current data read instruction or based on a playback instruction. When the measured data read request is generated based on the current data read instruction, a measured data read request is sent to at least one function module, to cause the at least one function module to read the measured data from the storage space in real time according to the measured data read request respectively, and process the measured data to observe various waveforms in real time. When the measured data read request is generated based on the playback instruction, a measured data read request is sent to at least one function module, to cause the at least one function module to read, from the storage space according to the measured data read request, the measured data in a page indicated by the playback instruction, respectively, and process the measured data in the page indicated by the playback instruction, so that a user calls relevant data as required for observation, analysis and comparison, that is, playback. For example, if the playback instruction indicates the measured data of the fifth page, the measured data of the fifth page is read from the storage space according to the read measured data request, and the measured data of the fifth page is processed.

The measured data read request is sent to at least one function module, to cause the at least one function module to read the measured data from the storage space according to the measured data read request, respectively, and process the measured data. Module-by-module processing may be performed on the measured data to achieve output and playback in a plurality of modes. In addition, when there are a plurality of function modules, the measured data may be processed synchronously.

5. The oscilloscope 20 respectively receives processing result information that is returned after the at least one function module processes the measured data, and outputs the processing result information. Each of the at least one function module processes the measured data and returns processing result information, that is, each function module returns one piece of processing result information to achieve outputting in a plurality of modes, so that the user may observe waveforms in a plurality of modes at the same time. The outputting, by the oscilloscope 20, the processing result information may include: sending the processing result information to the terminal device 30.

6. The terminal device 30 receives the processing result information, converts the processing result information into an image and displays the image on an interface. The displaying the image on an interface may include: displaying the image in a plurality of windows on the interface, an image displayed in one of the plurality of windows being an image obtained through conversion according to processing result information returned by one of the at least one function module; and/or displaying the image in a single window, the image displayed in the single window being an image obtained through conversion according to processing result information returned by all function modules of the at least one function module. For example, the at least one function module may include, but is not limited to, a spectrum module, a mathematical operation module, a decoding module, and the like. When multi-window display is performed on the interface, since the at least one function module includes three function modules, correspondingly, there are three windows for multi-window display. A spectrum graph obtained through conversion according to processing result information returned by the spectrum module is displayed in one of the plurality of windows. A mathematical operation image (an image obtained through addition, subtraction, multiplication and division processing) obtained through conversion according to processing result information returned by the mathematical operation module is displayed in another window of the plurality of windows. A decoding result obtained through conversion according to the processing result information returned by the decoding module is displayed in another window of the plurality of windows. In addition, three windows are displayed on the same interface at the same time. When single-window display is performed on the interface, images obtained through conversion according to processing result information returned by the three function modules are displayed in a same window. A spectrum graph obtained through conversion according to processing result information returned by the spectrum module, a mathematical operation image (an image obtained through addition, subtraction, multiplication and division processing) obtained through conversion according to processing result information returned by the mathematical operation module, and a decoding result obtained through conversion according to the processing result information returned by the decoding module are displayed in a same window. The user may choose to observe the image in a plurality of windows or observe the image in a single window as required.

In some other embodiments, the terminal device 30 may further receive an image scaling instruction to scale the image. For example, the terminal device 30 provides a selection tool, and the selection tool may be used to scale and display the selected image during the corresponding time period. When the image during the time period is displayed relatively intensively, the image scaling instruction may be used to magnify the image during the time period for easy observation. When the image during the time period is displayed relatively loosely, the image scaling instruction may be used to reduce the image during the time period to adjust the image within a display range suitable for a user to observe. The terminal device 30 may receive an image dragging instruction to drag the image, which is convenient for users to observe images in different time periods as required.

It should be noted that, in the embodiment of the present invention, the measured device 10 may be various types of electronic components, for example, electronic components of an automobile. The terminal device 30 may be a personal computer (PC), a tablet, a smart phone, or the like.

It should further be noted that in some other embodiments, functions of the oscilloscope 20 and the terminal device 30 may be integrated into a same device, that is, the device may implement all the functions of the oscilloscope 20 and the terminal device 30.

In the embodiment of the present invention, the measured data is stored in the storage space, to call relevant data from the storage space as needed for observation, analysis, comparison, and the like. In addition, the at least one function module reads and processes data from the storage space, respectively, to perform module-by-module processing on the measured data, thereby achieving the effect of outputting in a plurality of modes. Moreover, multi-window display or single-window display may be performed according to user needs.

### Embodiment 2

FIG. 3 is a schematic flowchart of a method for processing oscilloscope data according to an embodiment of the present invention. The method for processing the oscilloscope data provided in an embodiment of the present invention is applied to an oscilloscope, and may be performed by the oscilloscope 20 in FIG. 1.

Referring to FIG. 3, the method includes the following steps.

301: Measured data is collected.

The oscilloscope may collect measured data from a measured device according to a sampling frequency. The sampling frequency may be a default sampling frequency of an oscilloscope system, or may be a sampling frequency set by a user. The measured device is an electronic component of an automobile, and the like.

302: The measured data is stored in a storage space.

After the measured data is collected, the oscilloscope may store the measured data in a storage space. The storage space includes a storage space of the oscilloscope and a storage space that is of a terminal device and that is connected to an output end of the oscilloscope, that is, the measured data may be stored in the storage space of the oscilloscope, or the measured data may be stored in the storage space that is of the terminal device and that is connected to the output end of the oscilloscope. Because a size of the storage space of the oscilloscope is generally limited, the data that may be stored is limited, when the data amount of the measured data is greater than a preset data amount threshold, the measured data may be stored in the storage space of other devices, to resolve a problem that the oscilloscope cannot store a large amount of data.

It should be noted that, in some embodiments, the storage space is the storage space of the oscilloscope. When the data amount of the measured data is relatively small, the storage space of the oscilloscope may store the measured data.

303: A measured data read request is sent to at least one function module, to cause the at least one function module to read the measured data from the storage space according to the measured data read request, respectively, and process the measured data.

Each of the at least one function module may read the measured data from the storage space according to the measured data read request, and process the measured data respectively. For example, the at least one function module may include, but is not limited to, a spectrum module, a mathematical operation module, a decoding module, and the like. The spectrum module, the mathematical operation module and the decoding module may respectively read the measured data from the storage space and process the measured data respectively. The spectrum module processes the measured data, to display a frequency domain image, that is, a spectrum graph, on an interface. The mathematical operation module may perform a mathematical operation (such as addition, subtraction, multiplication and division) on the measured data, to display, on the interface, an image obtained after addition, subtraction, multiplication and division processing is performed on the measured data. The decoding module may decode the measured data, to display, on the interface, a decoding result obtained after the measured data is decoded.

The measured data read request is sent to at least one function module, to cause the at least one function module to read the measured data from the storage space according to the measured data read request, respectively, and process the measured data. Module-by-module processing may be performed on the measured data to achieve output and playback in a plurality of modes. In addition, when there are a plurality of function modules, the measured data may be processed synchronously.

304: Processing result information that is returned after the at least one function module processes the measured data is respectively received.

Each of the at least one function module processes the measured data and returns processing result information, that is, each function module returns one piece of processing result information to achieve outputting in a plurality of modes, so that the user may observe waveforms in a plurality of modes at the same time.

305: The processing result information is output.

The outputting, by the oscilloscope, the processing result information may include: directly displaying the processing result information on the oscilloscope; or converting the processing result information into an image for display as an image; sending the processing result information to an external terminal device for display on the terminal device, or the like. The terminal device is any of the following: a personal computer, a tablet and a smart phone.

It should be noted that, for technical details not described in detail in steps 301-305 in the embodiments of the present invention, reference may be made to the specific description of the foregoing embodiments.

In the embodiment of the present invention, the measured data is stored in the storage space, to call relevant data from the storage space as needed for observation, analysis, comparison or playback. In addition, the at least one function module reads and processes data from the storage space, respectively, to perform module-by-module processing on the measured data, thereby achieving the effect of outputting in a plurality of modes.

### Embodiment 3

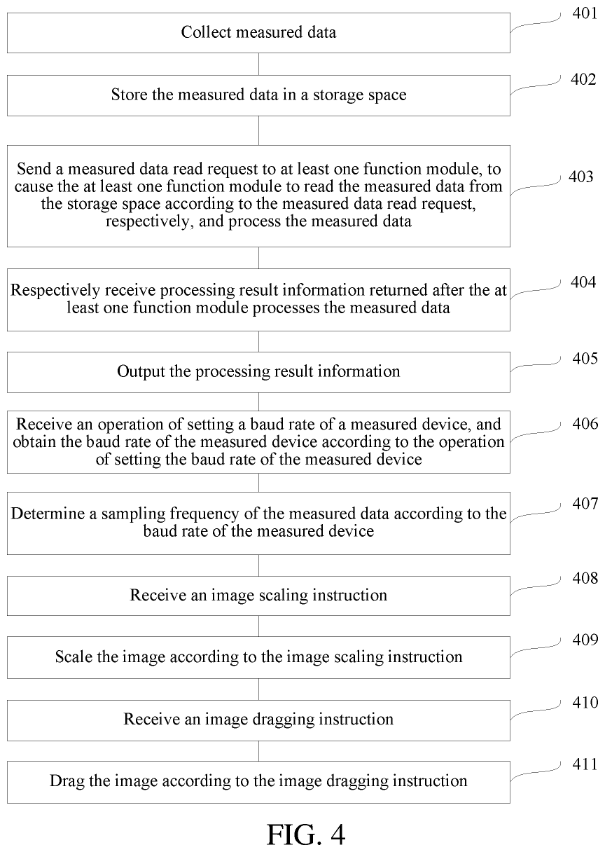

FIG. 4 is a schematic flowchart of a method for processing oscilloscope data according to another embodiment of the present invention. The method for processing the oscilloscope data provided in another embodiment of the present invention is applied to an oscilloscope, and may be performed by the oscilloscope 20 in FIG. 1.

Referring to FIG. 4, the method includes the following steps.

401: Measured data is collected.

The oscilloscope may collect measured data from a measured device according to a sampling frequency. The measured device is an electronic component of an automobile, and the like.

402: The measured data is stored in a storage space.

After the measured data is collected, the oscilloscope may store the measured data in a storage space. The storage space includes a storage space of the oscilloscope and a storage space that is of a terminal device and that is connected to an output end of the oscilloscope, that is, the measured data may be stored in the storage space of the oscilloscope, or the measured data may be stored in the storage space that is of the terminal device and that is connected to the output end of the oscilloscope. Because a size of the storage space of the oscilloscope is generally limited, the data that may be stored is limited, when the data amount of the measured data is greater than a preset data amount threshold, the measured data may be stored in the storage space of other devices, to resolve a problem that the oscilloscope cannot store a large amount of data. For example, the measured data is stored in the storage space of the terminal device. That is, the storing the measured data in a storage space may include: when a data amount of the measured data is greater than a preset data amount threshold of the storage space of the oscilloscope, storing the measured data in the storage space of the terminal device. The terminal device is any of the following: a personal computer, a tablet and a smart phone.

It should be noted that, in some embodiments, the storage space is the storage space of the oscilloscope. When the data amount of the measured data is relatively small, the storage space of the oscilloscope may store the measured data.

In order to facilitate quick reading of the measured data by the at least one function module, the measured data may be stored in pages. Specifically, the storing the measured data in a storage space includes: storing the measured data in pages on a screen-by-screen basis. The screen by which the measured data is stored in pages refers to a display area for displaying the measured data in the oscilloscope. The display area may be customized by the user. For example, ⅔, ⅓ of the screen of the oscilloscope is defined as the display area, or an entire screen of the oscilloscope is defined as the display area. The storing the measured data in pages on a screen-by-screen basis is specifically: obtaining resolution of the display area in advance, then calculating the amount of data displayed in a full screen according to the resolution, and then performing storing in pages according to the amount of data required for filling the full screen, so that the at least one function module can quickly read the measured data.

403: A measured data read request is sent to at least one function module, to cause the at least one function module to read the measured data from the storage space according to the measured data read request, respectively, and process the measured data.

Each of the at least one function module may read the measured data from the storage space according to the measured data read request, and process the measured data respectively. The at least one function module may include, but is not limited to, a spectrum module, a measurement module, a mathematical operation module, an analog module, a decoding module, and the like. The spectrum module, the measurement module, the mathematical operation module, the analog module and the decoding module may respectively read the measured data from the storage space and process the data respectively. The spectrum module processes the measured data from the storage space for displaying a frequency domain image, that is, a spectrum graph, on an interface. The measurement module does not perform conversion processing on the measured data for displaying the measured data on the interface directly. The mathematical operation module may perform a mathematical operation (such as addition, subtraction, multiplication and division) on the measured data, to display, on the interface, an image obtained after addition, subtraction, multiplication and division processing is performed on the measured data. The analog module converts the measured data into an analog signal for displaying the analog signal on the interface directly. The decoding module may decode the measured data, to display, on the interface, a decoding result obtained after the measured data is decoded.

The measured data read request is generated based on a current data read instruction or based on a playback instruction. The sending a measured data read request to at least one function module, to cause the at least one function module to read the measured data from the storage space according to the measured data read request, respectively, and process the measured data includes: when the measured data read request is generated based on the current data read instruction, sending a measured data read request to at least one function module, to cause the at least one function module to read the measured data from the storage space in real time according to the measured data read request respectively, and process the measured data to observe various waveforms in real time; and when the measured data read request is generated based on the playback instruction, sending a measured data read request to at least one function module, to cause the at least one function module to read, from the storage space according to the measured data read request, the measured data in a page indicated by the playback instruction, respectively, and process the measured data in the page indicated by the playback instruction, so that a user calls relevant data as required for observation, analysis and comparison, that is, playback.

The measured data read request is sent to at least one function module, to cause the at least one function module to read the measured data from the storage space according to the measured data read request, respectively, and process the measured data. Module-by-module processing may be performed on the measured data to achieve output and playback in a plurality of modes. In addition, when there are a plurality of function modules, the measured data may be processed synchronously.

404: Processing result information that is returned after the at least one function module processes the measured data is respectively received.

Each of the at least one function module processes the measured data and returns processing result information, that is, each function module returns one piece of processing result information to achieve outputting in a plurality of modes, so that the user may observe waveforms in a plurality of modes at the same time.

405: The processing result information is output.

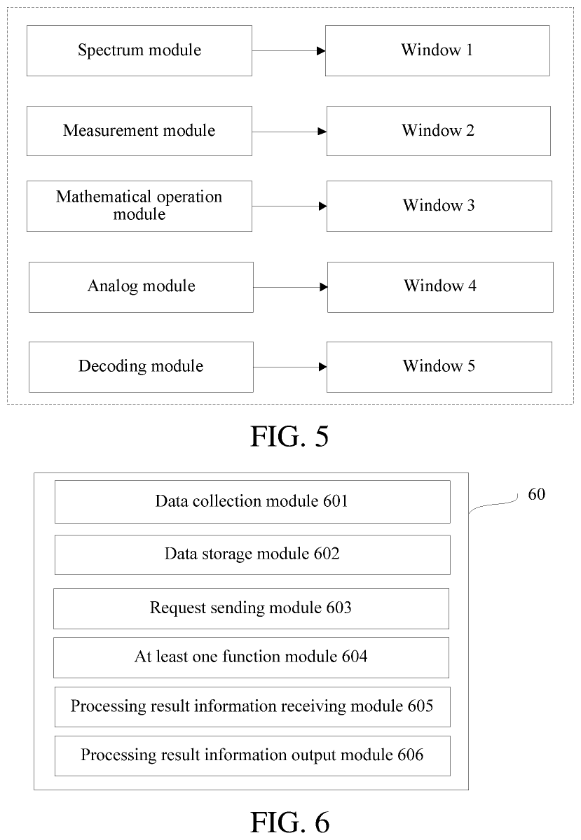

The outputting, by the oscilloscope, the processing result information may include: converting the processing result information into an image and displaying the image on an interface. The displaying the image on an interface includes: displaying the image in a plurality of windows on the interface, an image displayed in one of the plurality of windows being an image obtained through conversion according to processing result information returned by one of the at least one function module; and/or displaying the image in a single window, the image displayed in the single window being an image obtained through conversion according to processing result information returned by all function modules of the at least one function module. During the multi-window display, a correspondence between each of the at least one function module and a window is shown in FIG. 5. The at least one function module may include: a spectrum module, a measurement module, a mathematical operation module, an analog module and a decoding module. When multi-window display is performed on the interface, since the at least one function module includes five function modules, correspondingly, there are five windows for multi-window display. A spectrum graph obtained through conversion according to processing result information returned by the spectrum module is displayed in a window 1 of the plurality of windows. A measurement result (measured data obtained directly) obtained through conversion according to processing result information returned by the measurement module is displayed in window 2 of the plurality of windows. A mathematical operation image (an image obtained through addition, subtraction, multiplication and division processing) obtained through conversion according to processing result information returned by the mathematical operation module is displayed in a window 3 of the plurality of windows. An analog signal image (an image obtained after the measured data is converted into an analog signal) obtained through conversion according to processing result information returned by the analog module is displayed in a window 4 of the plurality of windows. A decoding result obtained through conversion according to the processing result information returned by the decoding module is displayed in a window 5 of the plurality of windows. In addition, five windows are displayed on a same interface at the same time. It should be noted that, in some other embodiments, the at least one function module may include but is not limited to the foregoing five function modules. For example, the at least one function module may further include a digital module and the like, and the number of windows is in a one-to-one correspondence with the number of the function modules. When single-window display is performed on the interface, images obtained through conversion according to processing result information returned by the five function modules are displayed in a same window. A spectrum graph obtained through conversion according to processing result information returned by the spectrum module, a measurement result obtained through conversion according to processing result information returned by the measurement module, a mathematical operation image obtained through conversion according to processing result information returned by the mathematical operation module, an analog signal image obtained through conversion according to processing result information returned by the analog module and a decoding result obtained through conversion according to the processing result information returned by the decoding module are displayed in a same window. In addition, the user may choose to observe the image in a plurality of windows or observe the image in a single window as required.

406: An operation of setting a baud rate of a measured device is received, and the baud rate of the measured device is obtained according to the operation of setting the baud rate of the measured device.

The baud rate refers to the amount of data generated by the measured device per second. The baud rate may be set in a customized manner according to requirements of the user. The operation of setting the baud rate of the measured device is received, so that the baud rate of the measured device may be obtained.

407: A sampling frequency at which the measured data is collected is determined according to the baud rate of the measured device.

The sampling frequency refers to the amount of data collected by the oscilloscope per second. Because the amount of data generated by the measured device per second and the amount of data collected by the oscilloscope per second may be inconsistent or even differ considerably, when the two are inconsistent or differ considerably, lots of invalid duplicated data exists in the data collected by the oscilloscope. Therefore, the sampling frequency at which the measured data is collected is determined according to the baud rate of the measured device. For example, the user sets the baud rate of the measured device to 100 Baud (Baud is a unit of the baud rate). In this case, the oscilloscope may receive the operation of setting the sampling frequency, thereby setting the sampling frequency of the oscilloscope to a value equal to the baud rate, that is, setting the sampling frequency to 100 Hz (Hz is the unit of frequency). When the sampling frequency is not significantly different from or equal to the baud rate, invalid data may be effectively eliminated to improve an obtaining rate of valid data, thereby saving space for the storage space.

408: An image scaling instruction is received.

The oscilloscope may receive an image scaling instruction to scale the image. The image scaling instruction may be generated based on an operation of the user.

409: The image is scaled according to the image scaling instruction.

The oscilloscope may scale the image according to the image scaling instruction. The entire image may be scaled, or a portion of the image may be scaled. For example, the oscilloscope provides a selection tool, and the selection tool may be used to scale and display the selected image during the corresponding time period. When the image during the time period is displayed relatively intensively, the image scaling instruction may be used to magnify the image during the time period for easy observation. When the image during the time period is displayed relatively loosely, the image scaling instruction may be used to reduce the image during the time period to adjust the image within a display range suitable for a user to observe.

410: An image dragging instruction is received.

The oscilloscope may receive an image dragging instruction to drag the image. The image dragging instruction may be generated based on an operation of the user.

411: The image is dragged according to the image dragging instruction.

The oscilloscope may drag the image according to the image dragging instruction. The image may be dragged left and right, or the image may be dragged up and down. The image is dragged left and right, which is convenient for users to observe images in different time periods as required.

It may be understood that, in some other embodiments, steps 406-411 may not be required in different embodiments. In addition, those skilled in the art may understand, according to the description of the embodiments of the present invention, that in different embodiments, if there is no contradiction, steps 401-411 may have different execution orders.

It should be noted that, for technical details not described in detail in steps 401-411 in the embodiments of the present invention, reference may be made to the specific description of the foregoing embodiments.

In the embodiment of the present invention, the measured data is stored in the storage space, to call relevant data from the storage space as needed for observation, analysis, comparison or playback. In addition, the at least one function module reads and processes data from the storage space, respectively, to perform module-by-module processing on the measured data, thereby achieving the effect of outputting in a plurality of modes. Moreover, multi-window display or single-window display may be performed according to user needs.

### Embodiment 4

FIG. 6 is a schematic diagram of an apparatus for processing oscilloscope data according to an embodiment of the present invention. The apparatus for processing the oscilloscope data provided in an embodiment of the present invention is applied to an oscilloscope.

Referring to FIG. 6, an apparatus 60 includes the following.

A data collection module 601 is configured to collect measured data.

The data collection module 601 may collect measured data from a measured device according to a sampling frequency. The sampling frequency may be a default sampling frequency of an oscilloscope system, or may be a sampling frequency set by a user. The measured device is an electronic component of an automobile, and the like.

A data storage module 602 is configured to store the measured data in a storage space.

After the data collection module 601 collects the measured data, the data storage module 602 may store the measured data in a storage space. The storage space includes a storage space of the oscilloscope and a storage space that is of a terminal device and that is connected to an output end of the oscilloscope, that is, the measured data may be stored in the storage space of the oscilloscope, or the measured data may be stored in the storage space that is of the terminal device and that is connected to the output end of the oscilloscope. Because a size of the storage space of the oscilloscope is generally limited, the data that may be stored is limited, when the data amount of the measured data is greater than a preset data amount threshold, the data storage module 602 may store the measured data in the storage space of other devices, to resolve a problem that the oscilloscope cannot store a large amount of data.

It should be noted that, in some embodiments, the storage space is the storage space of the oscilloscope. When the data amount of the measured data is relatively small, the data storage module 602 stores the measured data in the storage space of the oscilloscope.

A request sending module 603 is configured to send a measured data read request.

At least one function module 604 is configured to receive the measured data read request, read the measured data from the storage space according to the measured data read request, respectively, and process the measured data.

Each of the at least one function module 604 may read the measured data from the storage space according to the measured data read request, and process the measured data respectively. For example, the at least one function module may include, but is not limited to, a spectrum module, a mathematical operation module, a decoding module, and the like. The spectrum module, the mathematical operation module and the decoding module may respectively read the measured data from the storage space and process the measured data respectively. The spectrum module processes the measured data, to display a frequency domain image, that is, a spectrum graph, on an interface. The mathematical operation module may perform a mathematical operation (such as addition, subtraction, multiplication and division) on the measured data, to display, on the interface, an image obtained after addition, subtraction, multiplication and division processing is performed on the measured data. The decoding module may decode the measured data, to display, on the interface, a decoding result obtained after the measured data is decoded.

The at least one function module 604 reads the measured data from the storage space according to the measured data read request, respectively, and processes the measured data. Module-by-module processing may be performed on the measured data to achieve output and playback in a plurality of modes. In addition, when there are a plurality of function modules, the measured data may be processed synchronously.

A processing result information receiving module 605 is configured to respectively receive processing result information that is returned after the at least one function module processes the measured data.

After each of the at least one function module 604 processes the measured data, the processing result information receiving module 605 may respectively receive processing result information returned after the at least one function module processes the measured data, to achieve outputting in a plurality of modes, so that the user may observe waveforms in a plurality of modes at the same time.

A processing result information output module 606 is configured to output the processing result information.

The processing result information output module 606 may be specifically configured to: directly display the processing result information on the oscilloscope; or convert the processing result information into an image for display as an image; send the processing result information to an external terminal device for display on the terminal device, or the like. The terminal device is any of the following: a personal computer, a tablet and a smart phone.

It should be noted that, in the embodiment of the present invention, the apparatus 60 for processing the oscilloscope data may perform the method for processing the oscilloscope data provided in Embodiment 2 of the present invention, and has corresponding function modules and beneficial effects for performing the method. For technical details not described in detail in the embodiment of the apparatus 60 for processing the oscilloscope data, reference may be made to the method for processing the oscilloscope data provided in Embodiment 2 of the present invention.

### Embodiment 5

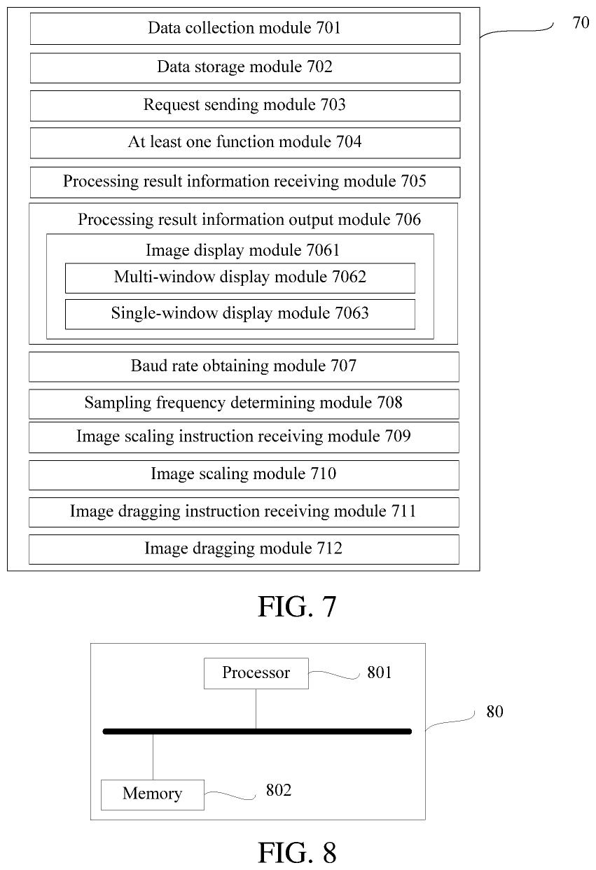

FIG. 7 is a schematic diagram of an apparatus for processing oscilloscope data according to another embodiment of the present invention. The apparatus for processing the oscilloscope data provided in another embodiment of the present invention is applied to an oscilloscope.

Referring to FIG. 7, an apparatus 70 includes the following.

A data collection module 701 is configured to collect measured data.

The data collection module 701 may collect measured data from a measured device according to a sampling frequency. The measured device is an electronic component of an automobile, and the like.

A data storage module 702 is configured to store the measured data in a storage space.

After the data collection module 701 collects the measured data, the data storage module 702 may store the measured data in a storage space. The storage space includes a storage space of the oscilloscope and a storage space that is of a terminal device and that is connected to an output end of the oscilloscope, that is, the data collection module 701 may store the measured data in the storage space of the oscilloscope, or may store the measured data in the storage space that is of the terminal device and that is connected to the output end of the oscilloscope. Because a size of the storage space of the oscilloscope is generally limited, the data that may be stored is limited, when the data amount of the measured data is greater than a preset data amount threshold, the data storage module 702 may store the measured data in the storage space of other devices, to resolve a problem that the oscilloscope cannot store a large amount of data. For example, the measured data is stored in the storage space of the terminal device. That is, the data storage module 702 is specifically configured to: when a data amount of the measured data is greater than a preset data amount threshold of the storage space of the oscilloscope, store the measured data in the storage space of the terminal device. The terminal device is any of the following: a personal computer, a tablet and a smart phone.

It should be noted that, in some embodiments, the storage space is the storage space of the oscilloscope. When the data amount of the measured data is relatively small, the data storage module 702 stores the measured data in the storage space of the oscilloscope.

In order to facilitate quick reading of the measured data by the at least one function module, the measured data may be stored in pages. Specifically, the data storage module 702 is configured to: store the measured data in pages on a screen-by-screen basis. The screen by which the measured data is stored in pages refers to a display area for displaying the measured data in the oscilloscope. The display area may be customized by the user. For example, ⅔, ⅓ of the screen of the oscilloscope is defined as the display area, or an entire screen of the oscilloscope is defined as the display area. The storing the measured data in pages on a screen-by-screen basis is specifically: obtaining resolution of the display area in advance, then calculating the amount of data displayed in a full screen according to the resolution, and then performing storing in pages according to the amount of data required for filling the full screen, so that the at least one function module can quickly read the measured data.

A request sending module 703 is configured to send a measured data read request.

The measured data read request is generated based on a current data read instruction or based on a playback instruction.

At least one function module 704 is configured to receive the measured data read request, read the measured data from the storage space according to the measured data read request, respectively, and process the measured data.

Each of the at least one function module 704 may read the measured data from the storage space according to the measured data read request, and process the measured data respectively. The at least one function module 704 may include, but is not limited to, a spectrum module, a measurement module, a mathematical operation module, an analog module, a decoding module, and the like. The spectrum module, the measurement module, the mathematical operation module, the analog module and the decoding module may respectively read the measured data from the storage space and process the data respectively. The spectrum module processes the measured data from the storage space for displaying a frequency domain image, that is, a spectrum graph, on an interface. The measurement module does not perform conversion processing on the measured data for displaying the measured data on the interface directly. The mathematical operation module may perform a mathematical operation (such as addition, subtraction, multiplication and division) on the measured data, to display, on the interface, an image obtained after addition, subtraction, multiplication and division processing is performed on the measured data. The analog module converts the measured data into an analog signal for displaying the analog signal on the interface directly. The decoding module may decode the measured data, to display, on the interface, a decoding result obtained after the measured data is decoded.

The measured data read request is generated based on a current data read instruction or based on a playback instruction. The at least one function module is specifically configured to: when the measured data read request is generated based on the current data read instruction, receive the measured data read request, read the measured data from the storage space in real time according to the measured data read request and process the measured data to observe various waveforms in real time; when the measured data read request is generated based on the playback instruction, receive a measured data read request, read, from the storage space according to the measured data read request, the measured data in a page indicated by the playback instruction, and process the measured data in the page indicated by the playback instruction, so that a user calls relevant data as required for observation, analysis and comparison, that is, playback.

The at least one function module 704 reads the measured data from the storage space according to the measured data read request, respectively, and processes the measured data. Module-by-module processing may be performed on the measured data to achieve output and playback in a plurality of modes. In addition, when there are a plurality of function modules, the measured data may be processed synchronously.

A processing result information receiving module 705 is configured to respectively receive processing result information that is returned after the at least one function module processes the measured data.

After each of the at least one function module 704 processes the measured data, the processing result information receiving module 705 may respectively receive processing result information returned after the at least one function module processes the measured data, to achieve outputting in a plurality of modes, so that the user may observe waveforms in a plurality of modes at the same time.

A processing result information output module 706 is configured to output the processing result information.

The processing result information output module 706 includes: an image display module 7061 configured to convert the processing result information into an image, and display the image on an interface. The image display module 7061 includes: a multi-window display module 7062 configured to convert the processing result information into an image and display the image in a plurality of windows on an interface, an image displayed in one of the plurality of windows being an image obtained through conversion according to processing result information returned by one of the at least one function module; and/or a single-window display module 7063 configured to convert the processing result information into an image and display the image in a single window, the image displayed in the single window being an image obtained through conversion according to processing result information returned by all function modules of the at least one function module. The user may choose to observe the image in a plurality of windows or observe the image in a single window as required.

A baud rate obtaining module 707 is configured to receive an operation of setting a baud rate of a measured device, and obtain the baud rate of the measured device according to the operation of setting the baud rate of the measured device.

The baud rate refers to the amount of data generated by the measured device per second. The baud rate may be set in a customized manner according to requirements of the user. The baud rate obtaining module 707 may obtain the baud rate of the measured device through receiving the operation of setting the baud rate of the measured device.

A sampling frequency determining module 708 is configured to determine, according to the baud rate of the measured device, a sampling frequency at which the measured data is collected.

The sampling frequency refers to the amount of data collected by the oscilloscope per second. Because the amount of data generated by the measured device per second and the amount of data collected by the oscilloscope per second may be inconsistent or even differ considerably, when the two are inconsistent or differ considerably, lots of invalid duplicated data exists in the data collected by the oscilloscope. Therefore, the sampling frequency determining module 708 determines, according to the baud rate of the measured device, the sampling frequency at which the measured data is collected. For example, the user sets the baud rate of the measured device to 100 Baud (Baud is a unit of the baud rate). In this case, the sampling frequency determining module 708 may receive the operation of setting the sampling frequency, thereby setting the sampling frequency of the oscilloscope to a value equal to the baud rate, that is, setting the sampling frequency to 100 Hz (Hz is the unit of frequency). When the sampling frequency is not significantly different from or equal to the baud rate, invalid data may be effectively eliminated to improve an obtaining rate of valid data, thereby saving space for the storage space.

An image scaling instruction receiving module 709 is configured to receive an image scaling instruction.

The image scaling instruction receiving module 709 may receive the image scaling instruction to achieve scaling of the image. The image scaling instruction may be generated based on an operation of the user.

An image scaling module 710 is configured to scale the image according to the image scaling instruction.

The image scaling module 710 may scale the image according to the image scaling instruction. The entire image may be scaled, or a portion of the image may be scaled. For example, the image scaling module 710 provides a selection tool, and the selection tool may be used to scale and display the selected image during the corresponding time period. When the image during the time period is displayed relatively intensively, the image scaling instruction may be used to magnify the image during the time period for easy observation. When the image during the time period is displayed relatively loosely, the image scaling instruction may be used to reduce the image during the time period to adjust the image within a display range suitable for a user to observe.

An image dragging instruction receiving module 711 is configured to receive an image dragging instruction.

The oscilloscope may receive an image dragging instruction to drag the image. The image dragging instruction may be generated based on an operation of the user.

An image dragging module 712 is configured to drag the image according to the image dragging instruction.

The image dragging module 712 may drag the image according to the image dragging instruction. The image may be dragged left and right, or the image may be dragged up and down. The image is dragged left and right, which is convenient for users to observe images in different time periods as required.

It should be noted that, in the embodiment of the present invention, the apparatus 70 for processing the oscilloscope data may perform the method for processing the oscilloscope data provided in Embodiment 3 of the present invention, and has corresponding function modules and beneficial effects for performing the method. For technical details not described in detail in the embodiment of the apparatus 70 for processing the oscilloscope data, reference may be made to the method for processing the oscilloscope data provided in Embodiment 3 of the present invention.

### Embodiment 6

FIG. 8 is a schematic structural diagram of hardware of an oscilloscope according to an embodiment of the present invention. As shown in FIG. 8, an oscilloscope 80 includes:

one or more processors 801 and a memory 802. One processor 801 is used as an example in FIG. 8.

The processor 801 and the memory 802 may be connected through a bus or in other manners. In FIG. 8, that the processor and the memory are connected through a bus is used as an example.

As a non-volatile computer readable storage medium, the memory 802 may be configured to store a non-volatile software program, a non-volatile computer executable program and a module, for example, a program instruction/module (for example, the data collection module 701, the data storage module 702, the request sending module 703, at least one function module 704, the processing result information receiving module 705, the processing result information output module 706, the baud rate obtaining module 707, the sampling frequency determining module 708, the image scaling instruction receiving module 709, the image scaling module 710, the image dragging instruction receiving module 711 and the image dragging module 712 that are shown in FIG. 7) corresponding to the method for processing the oscilloscope data provided in Embodiment 2 or Embodiment 3 of the present invention. The processor 801 executes various functional applications and data processing of the oscilloscope by running a non-volatile software program, an instruction and a module stored in the memory 802, that is, the method for processing the oscilloscope data provided in Embodiment 2 or Embodiment 3 of the method is implemented.

The memory 802 may include a program storage area and a data storage area, where the program storage area may store an operating system, an application required for at least one function, and the data storage area may store data and the like created according to use of the oscilloscope. In addition, the memory 802 may include a high speed random access memory, and may further include a non-volatile memory, such as at least one magnetic disk storage device, a flash memory device or other non-volatile solid state storage devices. In some embodiments, the memory 802 may optionally include remotely located memories relative to the processor 801, and these remote memories may be connected to the oscilloscope via a network. The embodiment of the network includes, but is not limited to, the Internet, an intranet, a local area network, a mobile communications network, and a combination thereof.

The one or more modules are stored in the memory 802. When executed by the one or more processors 801, the one or more modules perform the method for processing the oscilloscope data provided in Embodiment 2 or Embodiment 3 of the present invention, for example, perform step 401 to step 411 in the foregoing method in FIG. 4, or implement functions of the modules 701-712 in FIG. 7.

The oscilloscope may perform the method for processing the oscilloscope data provided in Embodiment 2 or Embodiment 3 of the present invention, and has corresponding functional modules and beneficial effects for performing the method. For technical details not described in detail in the embodiment of the oscilloscope, reference may be made to the method for processing the oscilloscope data provided in Embodiment 2 or Embodiment 3 of the present invention.

An embodiment of the present invention provides a computer program product. The computer program product includes a computer program stored on a non-volatile computer-readable storage medium. The computer program includes program instructions that, when executed by an oscilloscope, cause the oscilloscope to perform the method for processing the oscilloscope data provided in Embodiment 2 or Embodiment 3 of the present invention. For example, step 401 to step 411 in the foregoing method in FIG. 4 are performed, or functions of the modules 701-712 in FIG. 7 are implemented.

An embodiment of the present invention provides a non-volatile computer-readable storage medium. The computer-readable storage medium stores computer-executable instructions, which are used to cause an oscilloscope to perform the method for processing the oscilloscope data provided in Embodiment 2 or Embodiment 3 of the present invention. For example, step 401 to step 411 in the foregoing method in FIG. 4 are performed, or functions of the modules 701-712 in FIG. 7 are implemented.

It should be noted that, the apparatus embodiment described above is merely exemplary, and the modules described as separate components may or may not be physically separate, the components displayed as units may or may not be physical units, that is, may be located in one place, or may be distributed on a plurality of network units. Part or all of the modules may be selected according to actual needs to achieve the objective of the solution of this embodiment.

Through the description of the above embodiments, a person skilled in the art can clearly understand that the embodiments can be implemented by means of software plus a general hardware platform, and certainly, can also be implemented by hardware. A person of ordinary skill in the art can understand that all or part of the procedures in the method of the embodiment can be completed by computer program instructions related hardware. The program can be stored in a computer-readable storage medium, and when the program is executed, the procedure of the embodiment of each method may be included. The storage medium may be a magnetic disk, an optical disc, a read-only memory (ROM), or a random access memory (RAM).

Finally, it should be noted that: the above embodiments are only used to describe the technical solution of the present invention, but not limited thereto; under the thought of the present invention, the technical features in the above embodiments or different embodiments may also be combined. The steps can be implemented in any order, and there are many other variations of different aspects of the invention as described above, for brevity, they are not provided in the details; although the present invention is described in detail with reference to the foregoing embodiments, a person of ordinary skill in the art should understand that: it can still modify the technical solutions described in the foregoing embodiments, or equivalently replace some of the technical features; and these modifications or replacements do not deviate the spirit of the corresponding technical solutions from the implementation of the present invention.

1. A method for processing oscilloscope data, wherein the method comprises:
collecting measured data;
storing the measured data in a storage space;
sending a measured data read request to at least one function module, to cause the at least one function module to read the measured data from the storage space according to the measured data read request, respectively, and process the measured data;
respectively receiving processing result information that is returned after the at least one function module processes the measured data; and
outputting the processing result information.

2. The method according to claim 1, wherein the storing the measured data in a storage space comprises:
storing the measured data in pages on a screen-by-screen basis.

3. The method according to claim 1, wherein the measured data read request is generated based on a current data read instruction or based on a playback instruction.

4. The method according to claim 3, wherein the sending a measured data read request to at least one function module, to cause the at least one function module to read the measured data from the storage space according to the read measured data request, respectively, and process the measured data comprises:
when the measured data read request is generated based on the current data read instruction, sending a measured data read request to at least one function module, to cause the at least one function module to read the measured data from the storage space in real time according to the measured data read request, respectively, and process the measured data; and
when the measured data read request is generated based on the playback instruction, sending a measured data read request to at least one function module, to cause the at least one function module to read, from the storage space according to the measured data read request, the measured data in a page indicated by the playback instruction, respectively, and process the measured data in the page indicated by the playback instruction.

5. The method according to claim 1, wherein the outputting processing result information comprises:
converting the processing result information into an image, and displaying the image on an interface.

6. The method according to claim 5, wherein the displaying the image on an interface comprises:
displaying the image in a plurality of windows on the interface, an image displayed in one of the plurality of windows being an image obtained through conversion according to processing result information returned by one of the at least one function module; and/or
displaying the image in a single window on the interface, an image displayed in the single window being an image obtained through conversion according to processing result information returned by all function modules of the at least one function module.

7. The method according to claim 1, wherein the method further comprises:
receiving an operation of setting a baud rate of a measured device, and obtaining the baud rate of the measured device according to the operation of setting the baud rate of the measured device; and
determining, according to the baud rate of the measured device, a sampling frequency at which the measured data is collected.

8. The method according to claim 7, wherein the measured device is an electronic component of an automobile.

9. The method according to claim 1, wherein the storage space comprises a storage space of an oscilloscope and a storage space that is of a terminal device and that is connected to an output end of the oscilloscope; and
the storing the measured data in a storage space comprises:
when a data amount of the measured data is greater than a preset data amount threshold of the storage space of the oscilloscope, storing the measured data in the storage space of the terminal device.

10. An apparatus for processing oscilloscope data, wherein the apparatus comprises:
a data collection module configured to collect measured data;
a data storage module configured to store the measured data in a storage space;
a request sending module configured to send a measured data read request;
at least one function module configured to receive the measured data read request, read the measured data from the storage space according to the measured data read request, respectively, and process the measured data;
a processing result information receiving module configured to respectively receive processing result information that is returned after the at least one function module processes the measured data; and
a processing result information output module configured to output the processing result information.

11. The apparatus according to claim 10, wherein the data storage module is specifically configured to:
store the measured data in pages on a screen-by-screen basis.

12. The apparatus according to claim 10, wherein the measured data read request is generated based on a current data read instruction or based on a playback instruction.

13. The apparatus according to claim 12, wherein the at least one function module is specifically configured to:
when the measured data read request is generated based on the current data read instruction, receive the measured data read request, read the measured data from the storage space in real time according to the measured data read request, and process the measured data; and
when the measured data read request is generated based on the playback instruction, receive the measured data read request, read, from the storage space according to the measured data read request, the measured data in a page indicated by the playback instruction, and process the measured data in the page indicated by the playback instruction.

14. The apparatus according to claim 10, wherein the processing result information output module comprises:
an image display module configured to convert the processing result information into an image, and display the image on an interface.

15. The apparatus according to claim 14, wherein the image display module comprises:
a multi-window display module configured to convert the processing result information into an image and display the image in a plurality of windows on the interface, an image displayed in one of the plurality of windows being an image obtained through conversion according to processing result information returned by one of the at least one function module; and/or
a single-window display module configured to convert the processing result information into an image and display the image in a single window on the interface, an image displayed in the single window being an image obtained through conversion according to processing result information returned by all function modules of the at least one function module.

16. The apparatus according to claim 10, wherein the apparatus further comprises:
a baud rate obtaining module configured to receive an operation of setting a baud rate of a measured device, and obtain the baud rate of the measured device according to the operation of setting the baud rate of the measured device; and
a sampling frequency determining module configured to determine, according to the baud rate of the measured device, a sampling frequency at which the measured data is collected.

17. The apparatus according to claim 16, wherein the measured device is an electronic component of an automobile.

18. The apparatus according to claim 10, wherein the storage space is a storage space of an oscilloscope.

19. The apparatus according to claim 10, wherein the storage space comprises a storage space of an oscilloscope and a storage space that is of a terminal device and that is connected to an output end of the oscilloscope; and
the data storage module is specifically configured to:
when a data amount of the measured data is greater than a preset data amount threshold of the storage space of the oscilloscope, store the measured data in the storage space of the terminal device.

20. An oscilloscope, comprising:
at least one processor; and
a memory communicably connected to the at least one processor, wherein
the memory stores instructions that may be executed by the at least one processor and that is executed by the at least one processor, so that the at least one processor is configured to:
collect measured data;
store the measured data in a storage space;
send a measured data read request to at least one function module, to cause the at least one function module to read the measured data from the storage space according to the measured data read request, respectively, and process the measured data;
respectively receive processing result information that is returned after the at least one function module processes the measured data; and
output the processing result information.
